(19) United States
(12) Patent Application Publication
(10) Pub. No.: US 2012/0049166 A1
(43) Pub. Date: Mar. 1, 2012

(54) ORGANIC LIGHT EMITTING DIODE

(75) Inventors: JWO-HUEI JOU, HSINCHU (TW); SZU-HAO CHEN, HSINCHU (TW)

(73) Assignee: NATIONAL TSING HUA UNIVERSITY, HSINCHU (TW)

(21) Appl. No.: 13/037,639

(22) Filed: Mar. 1, 2011

(30) Foreign Application Priority Data
Aug. 25, 2010 (TW) 099128550

(51) Int. Cl. H01L 51/54; H01L 51/52

(52) U.S. Cl. 257/40; 257/101; 257/E51.018; 257/E51.041

(57) ABSTRACT

An organic light emitting diode includes an anode, a first emissive layer, a carrier modulating layer, a second emissive layer, and a cathode. The first emissive layer is located atop the anode, the carrier modulating layer is located atop the first emissive layer for helping holes to pass therethrough, the second emissive layer is located atop the carrier modulating layer, and the cathode is located atop the second emissive layer. And, the carrier modulating layer includes a primary material and at least one doping material.

### FIELD OF THE INVENTION

The present invention relates to an organic light emitting diode, and more particularly to an organic light emitting diode having a carrier modulating layer, in which doping materials of different energy levels are selectively doped in a primary material.

### BACKGROUND OF THE INVENTION

An organic electro-luminescence (EL) display is also referred to as an organic light emitting diode (OLED). In 1987, C. W. Tang, S. A. Van Slyke of Eastman Kodak Company developed the first OLED through vacuum vapor deposition. Materials for forming hole transporting layer and electron transporting layer are separately deposited on transparent indium tin oxide (ITO) glass, and a metal electrode is further vapor-deposited on the two transporting layers to form a self-luminescent OLED. The OLED has the advantages of high brightness, fast screen response time, compactness, full color, without visual angle difference, not requiring any LCD backlight module, reduced light source and low power consumption, and therefore becomes a new generation of display.

In the conventional OLED, there is included a carrier modulating layer for modulating carriers, i.e. electrons or holes, so that carriers reach carrier balance in the emissive layer. However, since the conventional material for the carrier modulating layer has a relatively high energy level, carriers could not easily pass the energy barrier at the carrier modulating layer to thereby result in low lighting efficiency of the OLED.

### SUMMARY OF THE INVENTION

A primary object of the present invention is to provide an organic light emitting diode to solve the problem of low lighting efficiency in the conventional organic light emitting diode.

To achieve the above and other objects, the organic light emitting diode according to a first embodiment of the present invention includes an anode, a first emissive layer, a carrier modulating layer, a second emissive layer, and a cathode. The first emissive layer is located atop the anode, the carrier modulating layer is located atop the first emissive layer for helping holes to pass therethrough, the second emissive layer is located atop the carrier modulating layer, and the cathode is located atop the second emissive layer. And, the carrier modulating layer includes a primary material and at least one doping material.

In the first embodiment, the doping material has an energy level in the highest occupied molecular orbital (HOMO) higher than that of the primary material.

And, the energy level of the doping material in the HOMO is higher than that of the first emissive layer.

In the first embodiment, the primary material is 4,4′-di(triphenylsilyl)-p-terphenyl (i.e. BSB).

In the first embodiment, the doping material is 2,7-bis(carbazo-9-yl)-9,9-ditolyfluorene (i.e. Spiro-2CBP).

To achieve the above and other objects, the organic light emitting diode according to a second embodiment of the present invention includes an anode, a first emissive layer, a carrier modulating layer, a second emissive layer, and a cathode. The carrier modulating layer is located atop the anode for helping holes to pass therethrough; the first emissive layer is located atop the carrier modulating layer; the second emissive layer is located atop the first emissive layer; and the cathode is located atop the second emissive layer. And, the carrier modulating layer includes a primary material and at least one doping material.

In the second embodiment, the doping material has an energy level in the highest occupied molecular orbital (HOMO) higher than that of the first emissive layer.

And, the energy level of the doping material in the highest occupied molecular orbital (HOMO) is lower than that of the anode.

In the second embodiment, the primary material is 4,4′-di(triphenylsilyl)-p-terphenyl (i.e. BSB).

In the second embodiment, the doping material is 2,7-bis(carbazo-9-yl)-9,9-ditolyfluorene (i.e. Spiro-2CBP).

To achieve the above and other objects, the organic light emitting diode according to a third embodiment of the present invention includes an anode, a first emissive layer, a carrier modulating layer, a second emissive layer, and a cathode. The first emissive layer is located atop the anode; the second emissive layer is located atop the first emissive layer; the carrier modulating layer is located atop the second emissive layer for stopping holes; and the cathode is located atop the carrier modulating layer. And, the carrier modulating layer includes a primary material and at least one doping material.

In the third embodiment, the doping material has an energy level in the HOMO lower than that of the primary material.

To achieve the above and other objects, the organic light emitting diode according to a fourth embodiment of the present invention includes an anode, a first emissive layer, a carrier modulating layer, a second emissive layer, and a cathode. The first emissive layer is located atop the anode; the carrier modulating layer is located atop the first emissive layer for helping electrons to pass therethrough; the second emissive layer is located atop the carrier modulating layer; and the cathode is located atop the second emissive layer. And, the carrier modulating layer includes a primary material and at least one doping material.

In the fourth embodiment, the doping material has an energy level in the lowest unoccupied molecular orbital (LUMO) lower than that of the primary material.

And, the energy level of the doping material in the LUMO is lower than that of the second emissive layer.

To achieve the above and other objects, the organic light emitting diode according to a fifth embodiment of the present invention includes an anode, a first emissive layer, a carrier modulating layer, a second emissive layer, and a cathode. The first emissive layer is located atop the anode; the second emissive layer is located atop the first emissive layer; the carrier modulating layer is located atop the second emissive layer for helping electrons to pass therethrough; and the cathode is located atop the carrier modulating layer. And, the carrier modulating layer includes a primary material and at least one doping material.

In the fifth embodiment, the doping material has an energy level in the LUMO lower than that of the second emissive layer.

And, the energy level of the doping material in the LUMO is higher than that of the cathode.

To achieve the above and other objects, the organic light emitting diode according to a sixth embodiment of the present invention includes an anode, a first emissive layer, a carrier modulating layer, a second emissive layer, and a cathode. The carrier modulating layer is located atop the anode for stopping electrons; the first emissive layer is located atop the carrier modulating layer; the second emissive layer is located atop the first emissive layer; and the cathode is located atop the second emissive layer. And, the carrier modulating layer includes a primary material and at least one doping material.

In the sixth embodiment, the doping material has an energy level in the LUMO higher than that of the primary material.

According to the above arrangements, the organic light emitting diode of the present invention has the following advantages:

Doping materials of different energy levels are selectively doped in the carrier modulating layer to increase the lighting efficiency of the organic light emitting diode.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 shows a conceptual view of an organic light emitting diode according to a first embodiment of the present invention and an energy level diagram thereof;

FIG. 2 shows the color gamut of the organic light emitting diode according to the first embodiment of the present invention;

FIG. 3 shows a conceptual view of an organic light emitting diode according to a second embodiment of the present invention and an energy level diagram thereof;

FIG. 4 shows a conceptual view of an organic light emitting diode according to a third embodiment of the present invention and an energy level diagram thereof;

FIG. 5 shows a conceptual view of an organic light emitting diode according to a fourth embodiment of the present invention and an energy level diagram thereof;

FIG. 6 shows a conceptual view of an organic light emitting diode according to a fifth embodiment of the present invention and an energy level diagram thereof; and

FIG. 7 shows a conceptual view of an organic light emitting diode according to a sixth embodiment of the present invention and an energy level diagram thereof.

### DETAILED DESCRIPTION OF THE PREFERRED EMBODIMENTS

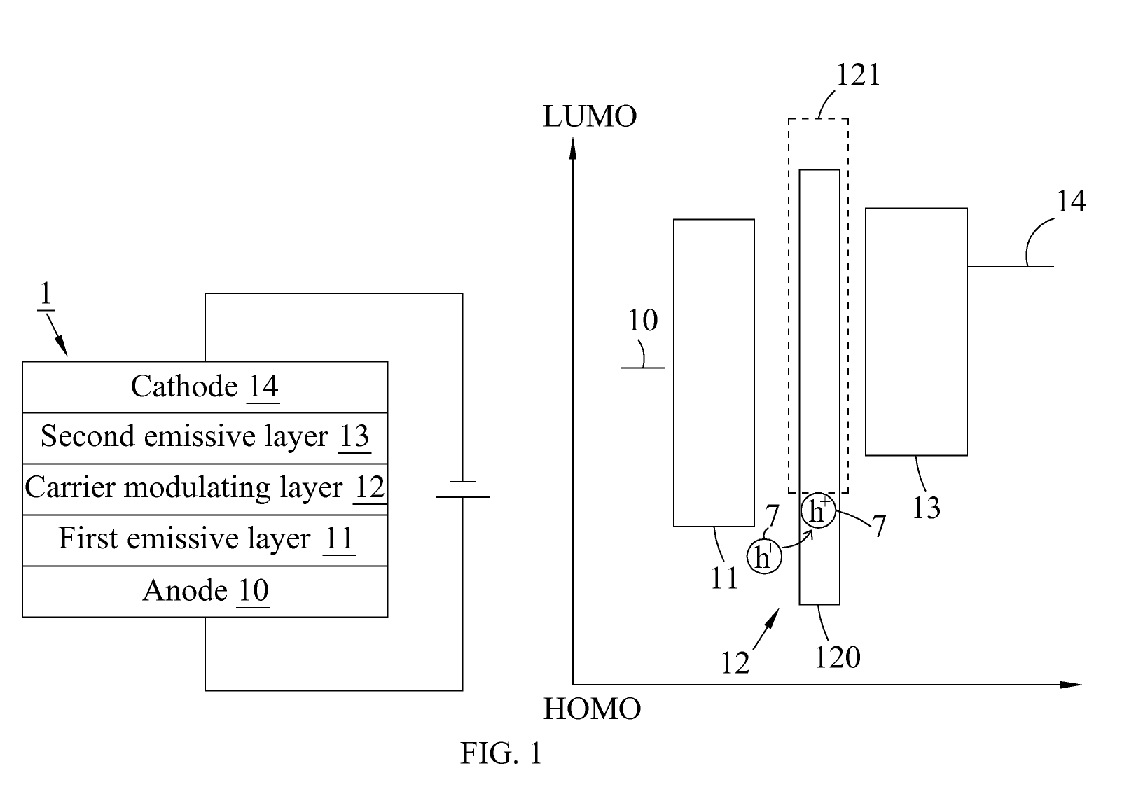

Please refer to FIG. 1 that shows a conceptual view of an organic light emitting diode 1 according to a first embodiment of the present invention and an energy level diagram thereof. As shown, the organic light emitting diode 1 includes an anode 10, a first emissive layer 11, a carrier modulating layer 12, a second emissive layer 13, and a cathode 14. The first emissive layer 11 is located atop the anode 10, the carrier modulating layer 12 is located atop the first emissive layer 11 for helping holes 7 to pass therethrough, the second emissive layer 13 is located atop the carrier modulating layer 12, and the cathode 14 is located atop the second emissive layer 14. The carrier modulating layer 12 includes a primary material 120 and at least one doping material 121. In the first embodiment, it is preferable to further include a hole injection layer or a hole transporting layer or both between the anode 10 and the first emissive layer 11, and an electron injection layer or an electron transporting layer or both between the second emissive layer 13 and the cathode 14. The first emissive layer 11 can be formed of a host material of 4,4′-Bis(N-carbazolyl)-1,1′-biphenyl (i.e. CBP) doped with a guest material of 16 wt % of iridium(III) bis[(4,6-difluorophenyl)-pyridinato-N,C-2′] picolinate (i.e. Flrpic). The second emissive layer 13 can be formed of a host material of 2,7-bis(carbazo-9-yl)-9,9-ditolyfluorene (i.e. Spiro-2CBP) doped with a guest material of 4 wt % of tris(2-phenylquinoline) iridium(III) (i.e. Ir(2-phq)₃). Further, one of the first emissive layer 11 and the second emissive layer 13 can be formed of a host material of CBP doped with a guest material of 12.5 wt % of fac tris(2-phenylpyridine) iridium (i.e. Ir(ppy)₃).

As can be seen from the energy level diagram in FIG. 1, in the first embodiment of the present invention, the doping material 121 has an energy level in the highest occupied molecular orbital (HOMO) higher than that of the primary material 120. Preferably, the energy level of the doping material 121 in the HOMO is also higher than that of the first emissive layer 11. In the first embodiment, the primary material 120 is 4,4′-di(triphenylsilyl)-p-terphenyl (i.e. BSB), and the doping material 121 is 2,7-bis(carbazo-9-yl)-9,9-ditolyfluorene (i.e. Spiro-2CBP). Preferably, the weight ratio of the primary material 120 (BSB) to the doping material (Spiro-2CBP) is 2:1.

Since the primary material of the carrier modulating layer 12 (BSB) is doped with a phosphorescent material, such as Spiro-2CBP, at a doping ratio of 2:1, an energy level path of the doping material 121 with an energy level value ranged between 2.33 and 6.5 electronic volts will appear in the energy level diagram. As a result, there would be more chances for the carriers, such as holes 7, to move from the first emissive layer 11, which has an energy level value ranged between 2.9 and 5.8 electronic volts, through the energy barrier at the carrier modulating layer 12 to reach at the second emissive layer 13 to enable an increased lighting efficiency of the whole organic light emitting diode 1.

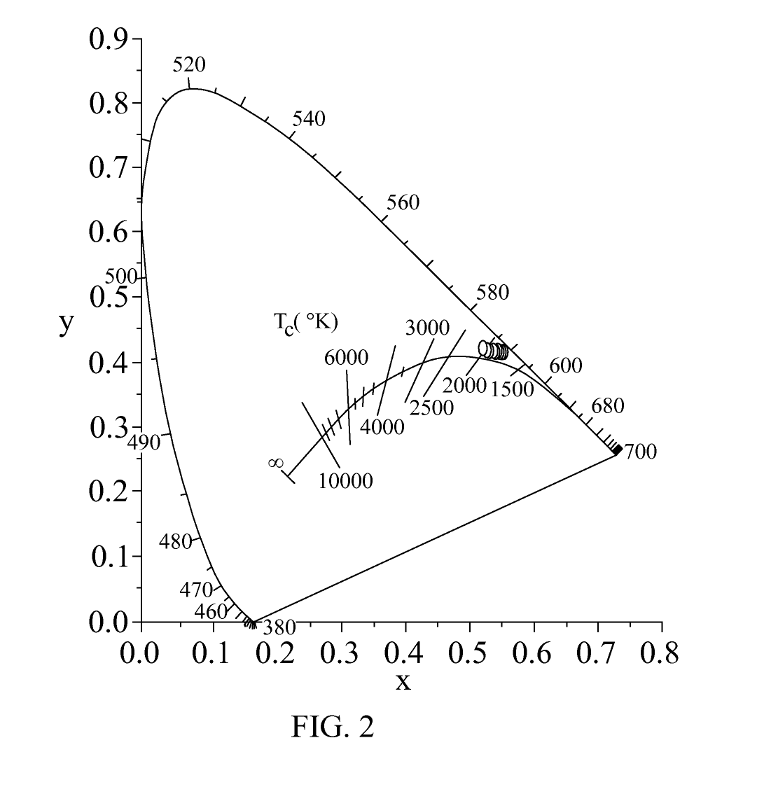

FIG. 2 shows the color gamut of the organic light emitting diode according to the first embodiment of the present invention. As shown, when the first emissive layer 11 includes a host material of CBP doped with a guest material of 16 wt % of Flrpic, and the second emissive layer 13 includes a host material of Spiro-2CBP doped with a guest material of 4 wt % of Ir(2-phq)₃, holes 7 can more easily pass through the energy barrier at the carrier modulation layer 12 to move to the second emissive layer 13 to recombine with electrons and emit light. Therefore, the color gamut of the whole organic light emitting diode tends to concentrate in the range defined by chromaticity coordinates (0.55, 0.43) and (0.53, 0.43). Please refer to the following table at the same time:

| | | Change in CIE |
|---|---|---|
| | | Chromaticity |
| | Lighting Efficiency at | Coordinates |
| OLED | 100 nits, 1000 nits | (beginning, end) |
| Conventional OLED | 17, 9 | (0.50, 0.42) |
| | | (0.31, 0.43) |
| OLED according to the first | 36, 28 | (0.55, 0.43) |
| embodiment of the present | | (0.53, 0.43) |
| invention | | |

As can be seen from the above table, when the doping material Spiro-2CBP is doped in the primary material BSB 120 at a doping ratio of 1:2 to form the carrier modulating layer 12, the organic LED according to the first embodiment of the present invention is able to have effectively upgraded lighting efficiency, which is more than twice as high as that of the conventional OLED. Particularly, in the high-brightness level, the lighting efficiency can be upgraded to be three times as high as before. However, it is noted the organic light emitting diode of the present invention has a relatively restricted color gamut. Nevertheless, it is understood by a person of ordinary skill in the art to which the present invention pertains, such restricted color gamut can still be applied according to the requirements for different light colors.

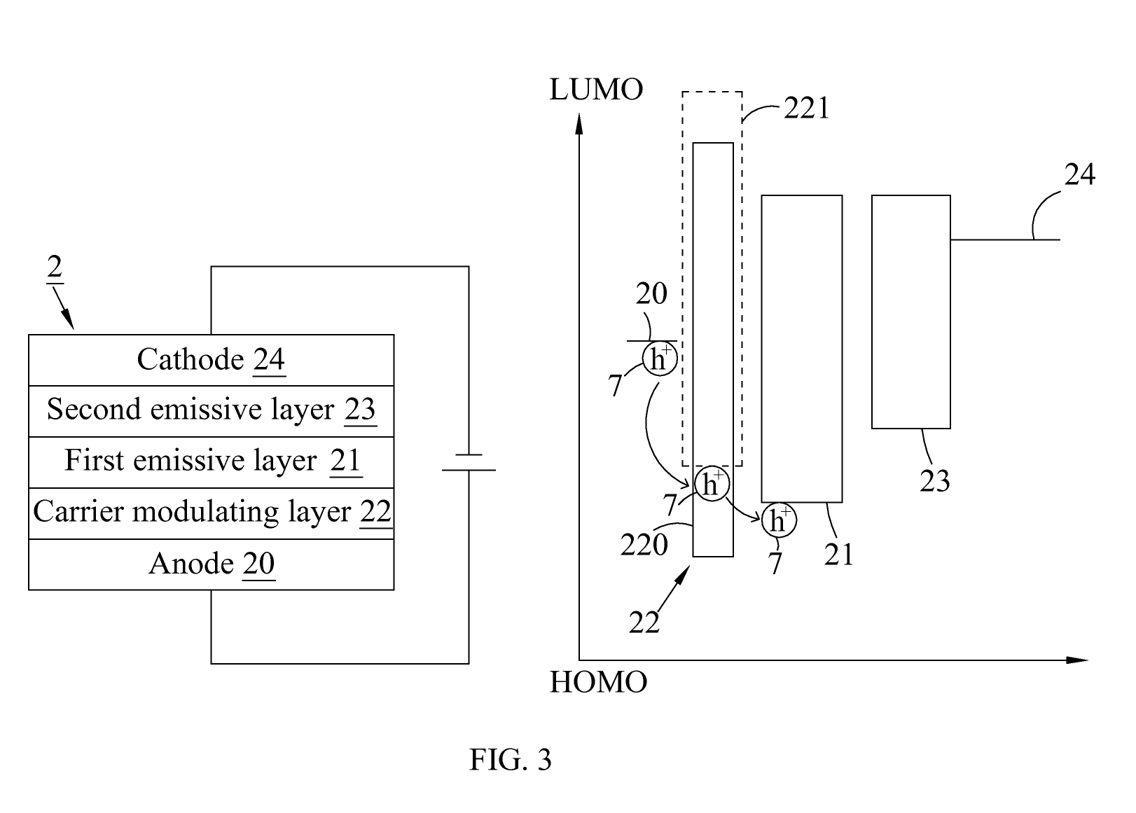

Please refer to FIG. 3 that shows a conceptual view of an organic light emitting diode 2 according to a second embodiment of the present invention and an energy level diagram thereof. As shown, the organic light emitting diode 2 includes an anode 20, a first emissive layer 21, a carrier modulating layer 22, a second emissive layer 23, and a cathode 24. The carrier modulating layer 22 is located atop the anode 20 for helping holes 7 to pass therethrough, the first emissive layer 21 is located atop the carrier modulating layer 22, the second emissive layer 23 is located atop the first emissive layer 21, and the cathode 24 is located atop the second emissive layer 23. The carrier modulating layer 22 includes a primary material 220 and at least one doping material 221. In the second embodiment, it is preferable to further include a hole injection layer or a hole transporting layer or both between the carrier modulating layer 22 and the first emissive layer 21, and an electron injection layer or an electron transporting layer or both between the second emissive layer 23 and the cathode 24. The second embodiment is different from the first embodiment mainly in that the doping material 221 has an energy level in the HOMO preferably higher than that of the first emissive layer 21, and more preferably lower than that of the anode 20. Since the energy level path of the doping material 221 of the carrier modulating layer 22 appeared in the energy level diagram is a stepped path, there would be more chances for holes 7 to move from the anode 20 through the energy barrier at the carrier modulating layer 22 to the first emissive layer 21, and accordingly, to enable an increased lighting efficiency of the whole organic light emitting diode 2.

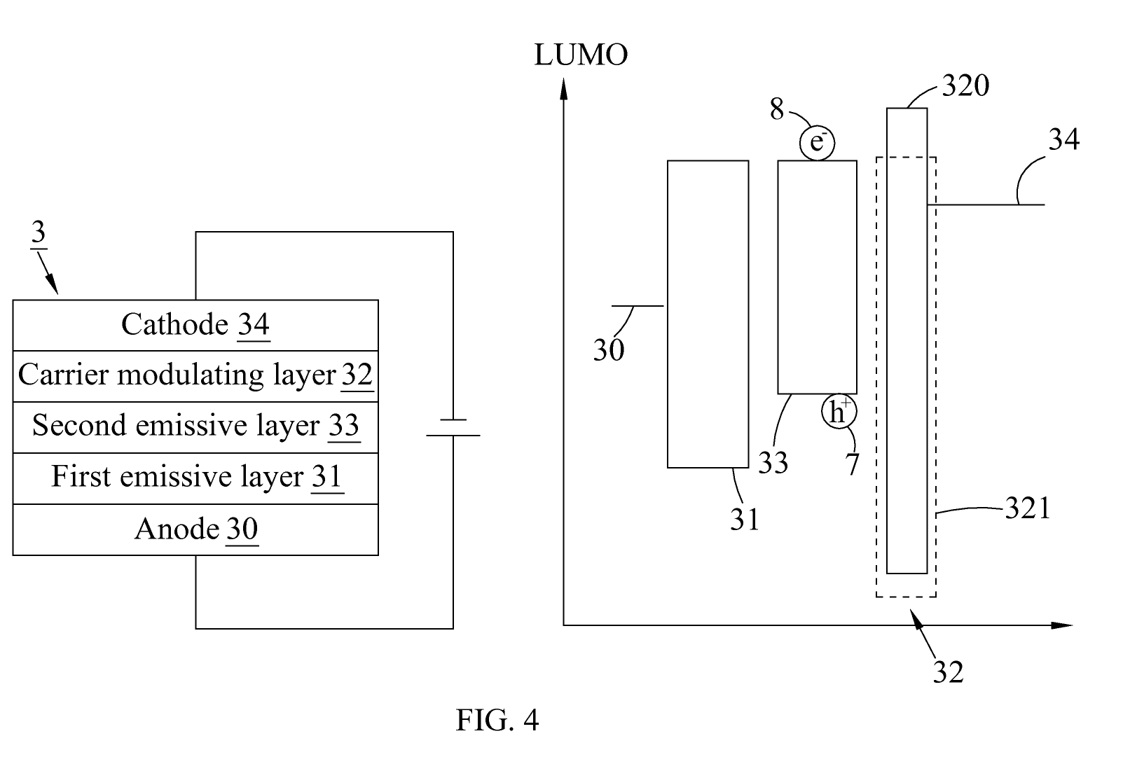

Please refer to FIG. 4 that shows a conceptual view of an organic light emitting diode 3 according to a third embodiment of the present invention and an energy level diagram thereof. As shown, the organic light emitting diode 3 includes an anode 30, a first emissive layer 31, a carrier modulating layer 32, a second emissive layer 33, and a cathode 34. The first emissive layer 31 is located atop the anode 30, the second emissive layer 33 is located atop the first emissive layer 31, the carrier modulating layer 32 is located atop the second emissive layer 33 for stopping holes 7 from passing therethrough, and the cathode 34 is located atop the carrier modulating layer 32. The carrier modulating layer 32 includes a primary material 320 and at least one doping material 321. In the third embodiment, it is preferable to further include a hole injection layer or a hole transporting layer or both between the anode 30 and the first emissive layer 31, and an electron injection layer or an electron transporting layer or both between the carrier modulating layer 32 and the second emissive layer 33.

The third embodiment is different from the first and the second embodiment mainly in that the doping material 321 has an energy level in the HOMO lower than that of the primary material 320. In this case, holes 7 that are not recombined with electrons 8 and about to move through the second emissive layer 33 will be stopped by the carrier modulating layer 32 and stay in the second emissive layer 32. That is, there are more chances for the holes 7 and the electrons 8 to recombine with one another and accordingly, to enable increased lighting efficiency of the whole organic light emitting diode 3.

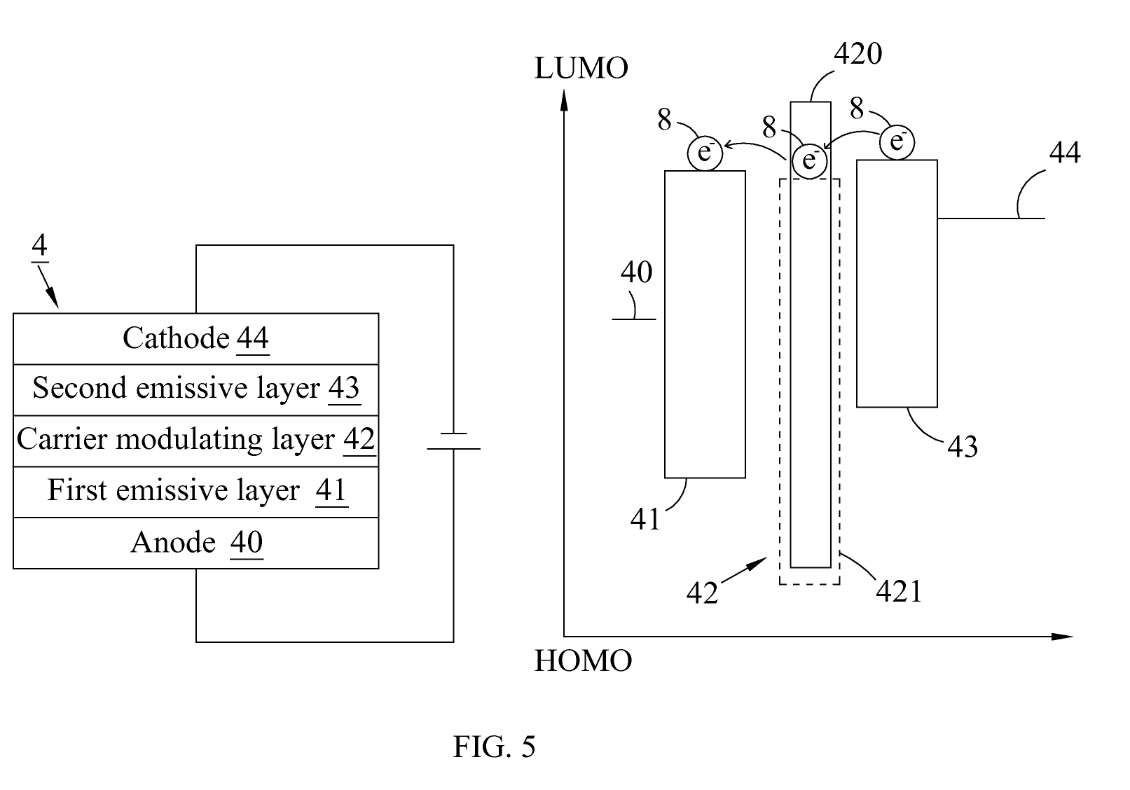

Please refer to FIG. 5 that shows a conceptual view of an organic light emitting diode 4 according to a fourth embodiment of the present invention and an energy level diagram thereof. As shown, the organic light emitting diode 4 includes an anode 40, a first emissive layer 41, a carrier modulating layer 42, a second emissive layer 43, and a cathode 44. The first emissive layer 41 is located atop the anode 40, the carrier modulating layer 42 is located atop the first emissive layer 41 for helping electrons 8 to pass therethrough, the second emissive layer 43 is located atop the carrier modulating layer 42, and the cathode is located atop the second emissive layer 43. The carrier modulating layer 42 includes a primary material 420 and at least one doping material 421. In the fourth embodiment, it is preferable to further include a hole injection layer or a hole transporting layer or both between the anode 40 and the first emissive layer 41, and an electron injection layer or an electron transporting layer or both between the cathode 44 and the second emissive layer 43.

The fourth embodiment is different from the first, the second and the third embodiment mainly in that the doping material 421 has an energy level in the lowest unoccupied molecular orbital (LUMO) preferably lower than that of the primary material 420, and more preferably lower than that of the second emissive layer 43. Since the energy level path of the doping material 421 of the carrier modulating layer 42 appeared in the energy level diagram is lower than that of the primary material 420, there would be more chances for the carriers, such as electrons 8, to move from the second emissive layer 43 through the energy barrier at the carrier modulating layer 42 to the first emissive layer 41, and accordingly, to enable an increased lighting efficiency of the whole organic light emitting diode 4.

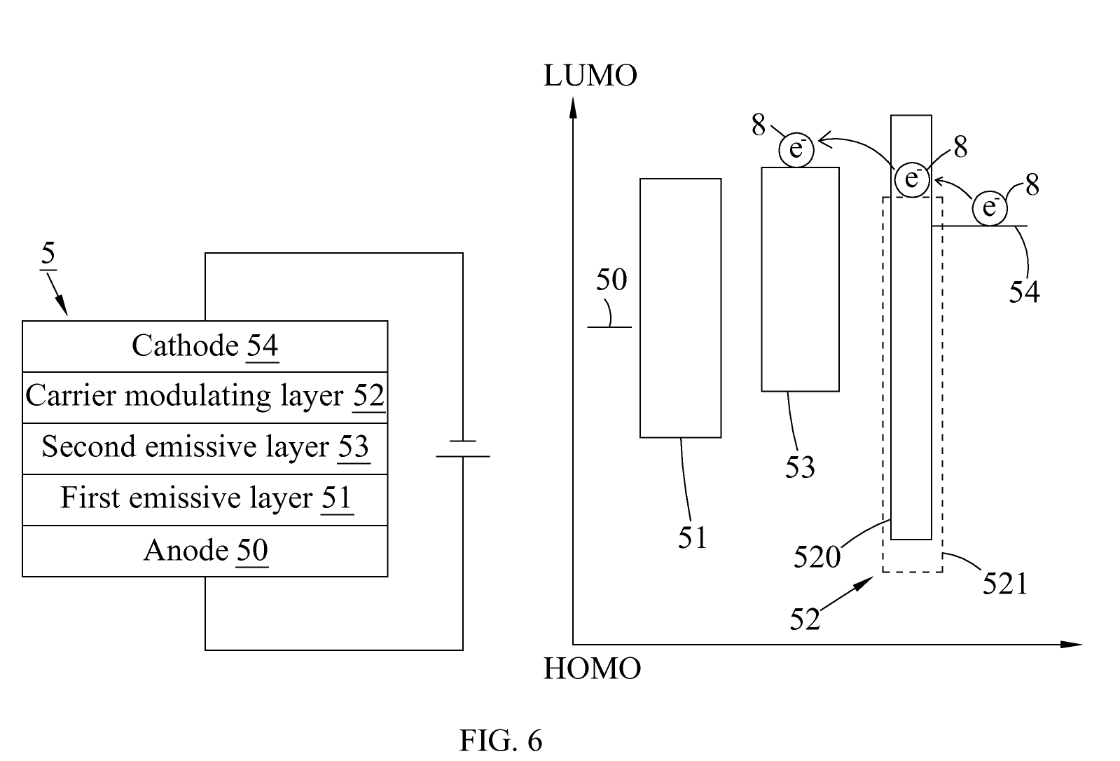

Please refer to FIG. 6 that shows a conceptual view of an organic light emitting diode 5 according to a fifth embodiment of the present invention and an energy level diagram thereof. As shown, the organic light emitting diode 5 includes an anode 50, a first emissive layer 51, a carrier modulating layer 52, a second emissive layer 53, and a cathode 54. The first emissive layer 51 is located atop the anode 50, the second emissive layer 53 is located atop the first emissive layer 51, the carrier modulating layer 52 is located atop the second emissive layer 53 for helping electrons 8 to pass therethrough, and the cathode 54 is located atop the carrier modulating layer 52. The carrier modulating layer 52 includes a primary material 520 and at least one doping material 521. In the fifth embodiment, it is preferable to further include a hole injection layer or a hole transporting layer or both between the anode 50 and the first emissive layer 51, and an electron injection layer or an electron transporting layer or both between the carrier modulating layer 52 and the second emissive layer 53.

The fifth embodiment is different from the first, the second, the third and the fourth embodiment mainly in that the doping material 521 has an energy level in the LUMO preferably lower than that of the second emissive layer 53 and larger than that of the cathode 54. Since the energy level path of the doping material 521 of the carrier modulating layer 52 appeared in the energy level diagram is a stepped energy level path, there would be more chances for the carriers, such as electrons 8, to move from the cathode 54 through the energy barrier at the carrier modulating layer 52 to the second emissive layer 53, and accordingly, to enable an increased lighting efficiency of the whole organic light emitting diode 5.

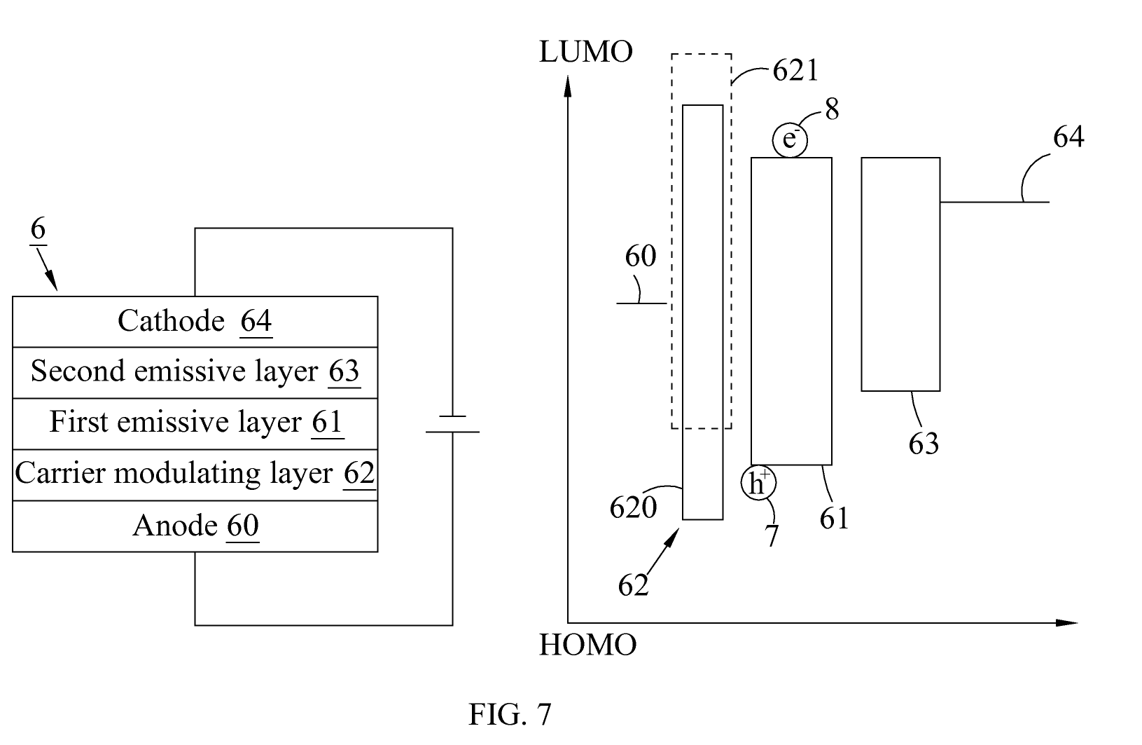

Please refer to FIG. 7 that shows a conceptual view of an organic light emitting diode 6 according to a sixth embodiment of the present invention and an energy level diagram thereof. As shown, the organic light emitting diode 6 includes an anode 60, a first emissive layer 61, a carrier modulating layer 62, a second emissive layer 63, and a cathode 64. The carrier modulating layer 62 is located atop the anode 60 for stopping electrons 8, the first emissive layer 61 is located atop the carrier modulating layer 62, the second emissive layer 63 is located atop the first emissive layer 61, and the cathode 64 is located atop the second emissive layer 63. The carrier modulating layer 62 includes a primary material 620 and at least one doping material 621. In the sixth embodiment, it is preferable to further include a hole injection layer or a hole transporting layer or both between the carrier modulating layer 62 and the first emissive layer 61, and an electron injection layer or an electron transporting layer or both between the cathode 64 and the second emissive layer 63.

The sixth embodiment is different from the previous embodiments mainly in that the doping material 621 has an energy level in the LUMO higher than that of the primary material 620. In this case, electrons 8 that are not recombined with holes 7 and about to move through the first emissive layer 61 will be stopped by the carrier modulating layer 62 and stay in the first emissive layer 61. Therefore, there would be more chances for the electrons 8 and the holes 7 to recombine with one another and accordingly, to enable increased lighting efficiency of the whole organic light emitting diode 6.

In conclusion, in the organic light emitting diode according to the present invention, doping materials of different energy levels are selectively doped in the carrier modulating layer to increase the lighting efficiency of the organic light emitting diode.

The present invention has been described with some preferred embodiments thereof and it is understood that many changes and modifications in the described embodiments can be carried out without departing from the scope and the spirit of the invention that is intended to be limited only by the appended claims.

What is claimed is:

1. An organic light emitting diode, comprising an anode; a first emissive layer located atop the anode; a carrier modulating layer located atop the first emissive layer for helping holes to pass therethrough; a second emissive layer located atop the carrier modulating layer; and a cathode located atop the second emissive layer; and wherein the carrier modulating layer includes a primary material and at least one doping material.

2. The organic light emitting diode as claimed in claim 1, wherein the doping material has an energy level in the highest occupied molecular orbital (HOMO) higher than that of the primary material.

3. The organic light emitting diode as claimed in claim 2, wherein the energy level of the doping material in the HOMO is larger than that of the first emissive layer.

4. The organic light emitting diode as claimed in claim 3, wherein the primary material is 4,4′-di(triphenylsilyl)-p-terphenyl (i.e. BSB).

5. The organic light emitting diode as claimed in claim 4, wherein the at least one doping material is 2,7-bis(carbazo-9-yl)-9,9-ditolyfluorene (i.e. Spiro-2CBP).

6. An organic light emitting diode, comprising an anode; a carrier modulating layer located atop the anode for helping holes to pass therethrough; a first emissive layer located atop the carrier modulating layer; a second emissive layer located atop the first emissive layer; and a cathode located atop the second emissive layer; and wherein the carrier modulating layer includes a primary material and at least one doping material.

7. The organic light emitting diode as claimed in claim 6, wherein the doping material has an energy level in the HOMO higher than that of the first emissive layer.

8. The organic light emitting diode as claimed in claim 7, wherein the energy level of the doping material in the HOMO is lower than that of the anode.

9. The organic light emitting diode as claimed in claim 8, wherein the primary material is 4,4′-di(triphenylsilyl)-p-terphenyl (i.e. BSB).

10. The organic light emitting diode as claimed in claim 9, wherein the at least one doping material is 2,7-bis(carbazo-9-yl)-9,9-ditolyfluorene (i.e. Spiro-2CBP).

11. An organic light emitting diode, comprising an anode; a first emissive layer located atop the anode; a second emissive layer located atop the first emissive layer; a carrier modulating layer located atop the second emissive layer for stopping holes; and a cathode located atop the carrier modulating layer; and wherein the carrier modulating layer includes a primary material and at least one doping material.

12. The organic light emitting diode as claimed in claim 11, wherein the doping material has an energy level in the HOMO lower than that of the primary material.

13. An organic light emitting diode, comprising an anode; a first emissive layer located atop the anode; a carrier modulating layer located atop the first emissive layer for helping electrons to pass therethrough; a second emissive layer located atop the carrier modulating layer; and a cathode located atop the second emissive layer; and wherein the carrier modulating layer includes a primary material and at least one doping material.

14. The organic light emitting diode as claimed in claim 13, wherein the doping material has an energy level in the lowest unoccupied molecular orbital (LUMO) lower than that of the primary material.

15. The organic light emitting diode as claimed in claim 14, wherein the energy level of the doping material in the LUMO is lower than that of the second emissive layer.

16. An organic light emitting diode, comprising an anode; a first emissive layer located atop the anode; a second emissive layer located atop the first emissive layer; a carrier modulating layer located atop the second emissive layer for helping electrons to pass therethrough; and a cathode located atop the carrier modulating layer; and wherein the carrier modulating layer includes a primary material and at least one doping material.

17. The organic light emitting diode as claimed in claim 16, wherein the doping material has an energy level in the LUMO lower than that of the second emissive layer.

18. The organic light emitting diode as claimed in claim 17, wherein the energy level of the doping material in the LUMO is higher than that of the cathode.

19. An organic light emitting diode, comprising an anode; a carrier modulating layer located atop the anode for stopping electrons; a first emissive layer located atop the carrier modulating layer; a second emissive layer located atop the first emissive layer; and a cathode located atop the second emissive layer; and wherein the carrier modulating layer includes a primary material and at least one doping material.

20. The organic light emitting diode as claimed in claim 19, wherein the doping material has an energy level in the LUMO higher than that of the primary material.
